(19) United States
(12) Patent Application Publication
(10) Pub. No.: US 2013/0089659 A1
(43) Pub. Date: Apr. 11, 2013

(54) Selenophene-Based Low Band Gap Active Layers by Chemical Vapor Deposition

(71) Applicants: Dhiman Bhattacharyya, Arlington, MA (US); Karen K. Gleason, Lexington, MA (US)

(72) Inventors: Dhiman Bhattacharyya, Arlington, MA (US); Karen K. Gleason, Lexington, MA (US)

(21) Appl. No.: 13/267,413

(22) Filed: Oct. 6, 2011

(51) Int. Cl. C09D 143/00; C23C 16/06; C23C 16/455

(52) U.S. Cl. 427/126.1; 427/255.28; 427/255.31; 524/547

(57) ABSTRACT

Described herein are methods of oxidative chemical vapor deposition of polyselenophene films onto non-conductive surfaces. The methods involve a single, dry step. The polyselenophene films formed by these methods have a lower band gap than the theoretically predicted value. Low-band-gap conjugated polymers are attractive for their applications in many devices including field effect transistors, light-emitting diodes, electrochromic devices, and photovoltaics.

### GOVERNMENT SUPPORT

This invention was made with government support under Grant No. W911NF-07-D-0004 awarded by the Army Research Office. The government has certain rights in this invention.

### BACKGROUND OF THE INVENTION

Low band gap organic materials are attractive due to their intrinsic electronic, optoelectronic, optical and non-linear optical properties. Recently, significant research efforts have focused on tuning the band gap of the polymers in order to improve the performance of devices, such as field-effect transistors, light-emitting diodes, electrochromic devices and photovoltaics. Most devices containing organic materials are fabricated by processes involving solvent-casting or spin-coating, so the insolubility of newly synthesized polymers is limiting. Many attempts to improve the solubility of the polymers have been reported. However, it is difficult to find a low band gap polymer with processable solubility properties. For example, poly(3-hexylthiophene), P3HT, is a well-known and extensively studied polymer system, which is widely used in making devices. It has good solubility properties and is easily processed for fabrication of devices, such as solar cells and transistors. The reported band gap of P3HT is ˜1.9 eV; however, a polymer with an even lower band gap is necessary for improved device efficiency. Therefore, a polymer system with a lower band gap is necessary, and a method to deposit thin films of this polymer for device fabrication is also in demand.

In search of new low band gap polymeric materials, various thiophene- and carbazole-based copolymers have been reported. Despite the fact that thiophene-based materials have received much more attention, there are not many reports published on its close analogue, selenophene. The unique properties of the selenium atom in selenophene provide many advantages which include: (1) Se—Se intermolecular interactions, which furnish wide bandwidth in organic conductors; (2) lower oxidation and reduction potentials of selenophene monomers, which may provide lower oxidation and reduction potentials in polyselenophene (pSe) than in polythiophene; (3) selenium is more polarizable than sulfur; (4) polyselenophenes have a lower band gap than polyhiophenes; and (5) pSe is less prone to oxidation due to its lower lying LUMO level.

Selenophene based homopolymers and copolymers have been previously reported. Recently, both theoretical and experimental research has described the desirability of these polymers as active low band gap materials. For example, the performance of solar cells improves when P3HT is replaced with selenophene-based P3HSe as an active layer in the same solar cell configuration. Additionally, oligoselenophenes have also been reported as an active layer in organic field effect transistors. Polyselenophene or selenophene-based copolymer thin films have previously been fabricated in two steps: (1) synthesis of the polymer, typically as a powder followed by (2) thin film deposition via spin-coating or vacuum sublimation. Spin coating is a commonly used technique for fabricating thin films; however, it is limited by the solubility of the polymer, and restricted to limited substrates. Overall, spin coating uses only 2-5% of the material and generates a huge amount of toxic waste. Additionally, polyselenophene or selenophene-based copolymer thin films have been electrochemically synthesized and deposited onto conductive substrates in a single step. However, it is difficult to deposit films on non-conductive substrates, for example, paper or plastics, by electrochemical techniques.

Oxidative chemical vapor deposition (oCVD) is a method by which the limitations of other standard methods may be avoided. For example, oCVD can simultaneously polymerize and deposit conjugated polymeric films in a controllable fashion. Moreover, polymers are deposited at low temperatures and without solvent; therefore, this method is compatible with virtually any substrate (that is, the deposition process is independent of the chemical nature and electrical conductivity of the substrates). In addition, the conformal nature of polymer films synthesized by oCVD can be employed uniformly to coat rough surfaces, including micro- or nano-structured substrates. And so, use of oCVD may prevent device shorting in a rough substrate and can be used for successful device fabrication on unconventional substrates, like paper. oCVD has been shown to grow uniform and conformal conducting polymers and copolymers on different substrates. Unlike vapor phase polymerization (VPP), where substrate is pretreated with a layer of oxidant, oCVD involves simultaneous exposure of the substrate to the oxidant and monomer vapors, which makes oCVD more compatible with various substrates. Moreover, the use of vapor deposition removes the requirement that the polymer be soluble. Hence, monomers without soluble side chains can be explored, opening a wider range of materials for consideration as active layers. The simplicity of oCVD can further be extended to patterned films using shadow masking Thus, synthesis, thin film growth, and patterning are achieved simultaneously, a process termed vapor printing. FIG. 8 shows comparisons of various processes with oCVD for synthesis and thin film fabrication of conjugated polymers.

The oCVD syntheses of PEDOT and copolymers PEDOT using FeCl₃, CuCl₂, or Br₂ as the oxidant have been previously reported.

### SUMMARY OF THE INVENTION

In certain embodiments, the invention relates to a composition comprising a coating on a surface of a substrate, wherein the coating comprises a polymer comprising selenophene repeat units.

In certain embodiments, the invention relates to a method of forming a coating on a surface of a substrate, comprising the steps of:
contacting the surface of the substrate with a gaseous metal-containing oxidant, thereby forming an oxidant-enriched surface; and
contacting the oxidant-enriched surface with a gaseous monomer, thereby forming a polymer-coated surface;
wherein the gaseous monomer is optionally substituted selenophene.

In certain embodiments, the invention relates to a method of forming any one of the aforementioned compositions, comprising the steps of:
contacting the surface of the substrate with a gaseous metal-containing oxidant, thereby forming an oxidant-enriched surface; and
contacting the oxidant-enriched surface with a gaseous monomer, thereby forming a polymer-coated surface;
wherein the gaseous monomer is optionally substituted selenophene.

### BRIEF DESCRIPTION OF THE FIGURES

FIG. 1 depicts a comparison of FT-IR spectra of polyselenophene [A] powder from solution synthesis and [B] thin film grown by the oCVD technique. [A1] and [B1] are images of solution synthesized pSe powder and oCVD grown pSe thin film on glass, respectively.

FIG. 2 depicts high resolution C 1s and Se 3d X-ray photoelectron spectra of a polyselenophene film synthesized by oCVD.

FIG. 3 depicts a UV-Vis spectrum of oCVD synthesized polyselenophene film on glass. The onset of absorption was found to be 720 nm, which corresponds to the band gap of the polymer at 1.72 eV. Optical band gap was calculated according to the relation: E_{g}=ΔE=hc/λ=6.624×10⁻³⁴×3.0×10⁸×10⁹/λ×1.602×10¹⁹=1240.15/λ (eV), where h is the Planck constant, c is the speed of light, and λ is the onset of absorption wavelength of the polymer film (unit: nm).

FIG. 4 depicts the FT-IR peak assignments and peak positions for oCVD- and solution-synthesized polyselenophene.

FIG. 5 depicts SEM images of ˜750 nm thick layer of oCVD-deposited [A] polyselenophene film on the surface of a silicon wafer and [B] a cross-sectional view of the same film on a trench silicon wafer.

FIG. 6 depicts AFM topographic images (10 μm×10 μm) of oCVD-deposited polyselenophene films of two different thicknesses: [A] 100 nm and [B] 750 nm. Inset figures show higher magnification images (1 μm×1 μm) of the respective films.

FIG. 7 depicts advancing and receding contact angles of oCVD-synthesized pSe films of two different thicknesses, 750 nm (thick films) and 100 nm (thin films), respectively.

FIG. 8 depicts a comparative study of various synthetic routes to conjugated polymers.

FIG. 9 depicts [A] a schematic of an oCVD reactor, and [B] and [C] show the α,α′ and α,β couplings of the selenophene rings in polyselenophene.

### DETAILED DESCRIPTION OF THE INVENTION

### Overview

In certain embodiments, the invention relates to the vapor-phase synthesis of an active layer. In certain embodiments, the active layer is polyselenophene. In certain embodiments, the invention relates to the formation of polyselenophene thin films directly from selenophene monomer vapor via oCVD. In certain embodiments, iron chloride is used as an oxidant. In certain embodiments, the measured band gap of pSe fabricated by oCVD is 0.14 eV lower than the theoretically predicted values. In certain embodiments, the invention relates to a method that avoids the use of hazardous solvents and the release of toxic waste to the environment.

### Definitions

For convenience, certain terms employed in the specification, examples, and appended claims are collected here.

“CVD” as used herein is an abbreviation for chemical vapor deposition.

As used herein, the term “surface” or “surfaces” or “substrates” can mean any surface of any material, including glass, plastics, metals, polymers, paper, fabric and the like. It can include surfaces constructed out of more than one material, including coated surfaces. Importantly, all surfaces/substrates of the invention can react with the oxidants/catalysts of the invention, resulting in the covalent attachment of the polymer coating to the surface/substrate.

A “dopant anion,” as used herein, provides stability enhancement for electroactive polymers. The dopant may be any compound as long as it has a doping ability (i.e., stabilizing ability). For example, an organic sulfonic acid, an inorganic sulfonic acid, an organic carboxylic acid or salts thereof, such as a metal salt or an ammonium salt may be used. The method for adding the dopant is not limited and the compound may be added to the oxidizing agent and/or the monomer, may be allowed to be present together at the time of polymerization or may be added by other methods. In certain embodiments, the dopant molecule comprises aqueous solutions of the acids selected from the group consisting of phosphoric acid, triflic acid, hydrochloric acid, methanesulfonic acid, oxalic acid, pyruvic acid, and acrylic acid, or a poly anion incorporating one or more of the aforementioned types of acids.

It will be understood that “substitution” or “substituted with” includes the implicit proviso that such substitution is in accordance with permitted valence of the substituted atom and the substituent, and that the substitution results in a stable compound, e.g., which does not spontaneously undergo transformation, such as by rearrangement, cyclization, elimination, or other reaction.

The term “substituted” is also contemplated to include all permissible substituents of organic compounds. In a broad aspect, the permissible substituents include acyclic and cyclic, branched and unbranched, carbocyclic and heterocyclic, aromatic and nonaromatic substituents of organic compounds. Illustrative substituents include, for example, those described herein above. The permissible substituents may be one or more and the same or different for appropriate organic compounds. For purposes of this invention, the heteroatoms, such as nitrogen may have hydrogen substituents and/or any permissible substituents of organic compounds described herein which satisfy the valences of the heteroatoms. This invention is not intended to be limited in any manner by the permissible substituents of organic compounds.

For purposes of this invention, the chemical elements are identified in accordance with the Periodic Table of the Elements, CAS version, “Handbook of Chemistry and Physics”, 67th Ed., 1986-87, inside cover.

The phrase “polydispersity index” refers to the ratio of the “weight average molecular weight” to the “number average molecular weight” for a particular polymer; it reflects the distribution of individual molecular weights in a polymer sample.

The phrase “weight average molecular weight” refers to a particular measure of the molecular weight of a polymer. The weight average molecular weight is calculated as follows: determine the molecular weight of a number of polymer molecules; add the squares of these weights; and then divide by the total weight of the molecules.

The phrase “number average molecular weight” refers to a particular measure of the molecular weight of a polymer. The number average molecular weight is the common average of the molecular weights of the individual polymer molecules. It is determined by measuring the molecular weight of n polymer molecules, summing the weights, and dividing by n.

Oxidative Chemical Vapor Deposition (oCVD)

In certain embodiments, oxidative chemical vapor deposition takes place in a reactor. In certain embodiments, precursor molecules, consisting essentially of a chemical metal-containing oxidant and a monomer species, are fed into the reactor. In certain embodiments, this process occurs at a range of pressures from atmospheric pressure to low vacuum. In certain embodiments, the pressure is from about 15 mtorr to about 760 torr. In certain embodiments, the pressure is from about 15 mtorr to about 500 mtorr. In certain embodiments, the pressure is about 15 mtorr, about 30 mtorr, about 50 mtorr, about 75 mtorr, about 100 mtorr, about 125 mtorr, about 150 mtorr, about 175 mtorr, about 200 mtorr, about 225 mtorr, about 250 mtorr, about 275 mtorr, about 300 mtorr, about 325 mtorr, about 350 mtorr, about 375 mtorr, about 400 mtorr, about 425 mtorr, about 450 mtorr, about 475 mtorr, or about 500 mtorr.

In certain embodiments, chemical metal-containing oxidant species are heavy, but can be sublimed onto a substrate surface using a carrier gas and a heated, porous crucible installed inside the reactor directly above the sample stage. In certain embodiments, the oxidant source is installed on the exterior of the vacuum chamber. In certain embodiments, evaporation of the oxidant takes place in a resistively heated container inside the reaction chamber. In certain embodiments, evaporation of the oxidant takes place in a resistively heated container inside the reaction chamber underneath the substrate surface to be coated. In certain embodiments, the monomer species is delivered from a source external to the reactor. In certain embodiments, the metal-containing oxidant forms a thin, conformational layer on the substrate surface, which reacts with monomer molecules as they adsorb. Oxidants in the vapor form can also be delivered for this polymerization process, for example, bromine (Br₂) and transition-metal-containing liquid oxidants (e.g., VOCl₃, VOCl₄).

In certain embodiments, acid-catalyzed side reactions may be reduced or eliminated using one or more the following techniques: introducing a base, such as pyridine, to react with any acid that is formed in situ; heating the substrate to temperatures above about 60° C., about 70° C., about 80° C. or about 90° C., for example, to accelerate evaporation of the acid as it is formed; and biasing the substrate with a positive charge using a DC power supply to favor the oxidation of monomeric and oligomeric species adsorbed on the substrate. In certain embodiments, biasing also provides directionality to charged oligomers during polymer chain growth. In certain embodiments, the ordering of the polymer chains that results is expected to contribute to higher electrical conductivities.

In certain embodiments, the deposited film then may be heated, sometimes under vacuum (e.g., at about 15 mmHg, about 30 mmHg, or about 45 mmHg), to remove unreacted monomer. In certain embodiments, rinsing the dried film in a solvent like methanol or water can remove reacted metal-containing oxidant from the film, in some cases changing the color of the film. In certain embodiments, rinsing the dried film in a solution of “dopant” ionic salts, such as NOPF₆ in acetonitrile, can promote the oxidized form of a conducting polymer by balancing positive charges that are induced along the polymer chain with anions from the salt.

### Polymer-Coated Surfaces of the Invention

In certain embodiments, the invention relates to a composition comprising a coating on a surface of a substrate, wherein the coating comprises a polymer comprising selenophene repeat units.

In certain embodiments, the invention relates to any one of the aforementioned compositions, wherein the coating comprises a polymer comprising optionally substituted selenophene repeat units.

In certain embodiments, the invention relates to any one of the aforementioned compositions, wherein the coating comprises a polymer comprising unsubstituted selenophene repeat units.

In certain embodiments, the invention relates to any one of the aforementioned compositions, wherein the coating comprises a polymer comprising α,α′- or α,β-coupled selenophene repeat units. In certain embodiments, the invention relates to any one of the aforementioned compositions, wherein the coating comprises a polymer comprising α,α′- and α,β-coupled selenophene repeat units.

In certain embodiments, the invention relates to any one of the aforementioned compositions, wherein the coating is of a substantially uniform thickness.

In certain embodiments, the invention relates to any one of the aforementioned compositions, wherein the thickness of the coating does not vary more than 10% over the surface.

In certain embodiments, the invention relates to any one of the aforementioned compositions, wherein the thickness of the coating does not vary more than 5% over the surface.

In certain embodiments, the invention relates to any one of the aforementioned compositions, wherein the thickness of the coating is from about 50 nm to about 1500 nm. In certain embodiments, the invention relates to any one of the aforementioned compositions, wherein the thickness of the coating is about 80 nm, about 90 nm, about 100 nm, about 125 nm, about 150 nm, about 175 nm, about 200 nm, about 225 nm, about 250 nm, about 275 nm, about 300 nm, about 325 nm, about 350 nm, about 375 nm, about 400 nm, about 425 nm, about 450 nm, about 475 nm, about 500 nm, about 525 nm, about 550 nm, about 575 nm, about 600 nm, about 625 nm, about 650 nm, about 675 nm, about 700 nm, about 725 nm, about 750 nm, about 775 nm, about 800 nm, about, 825 nm, about 850 nm, about 875 nm, or about 900 nm.

In certain embodiments, the invention relates to any one of the aforementioned compositions, wherein the coating is conductive.

In certain embodiments, the invention relates to any one of the aforementioned compositions, wherein the coating has a conductivity of between about 0 S/cm and about 150 S/cm.

In certain embodiments, the invention relates to any one of the aforementioned compositions, wherein the coating further comprises a metal-containing oxidant selected from the group consisting of iron(III) chloride, iron(III) tosylate, potassium iodate, potassium chromate, ammonium sulfate and tetrabutylammonium persulfate.

In certain embodiments, the invention relates to any one of the aforementioned compositions, wherein the coating further comprises iron(III) chloride.

In certain embodiments, the invention relates to any one of the aforementioned compositions, wherein the coating further comprises iron ions.

In certain embodiments, the invention relates to any one of the aforementioned compositions, wherein the coating further comprises chloride ions.

In certain embodiments, the invention relates to any one of the aforementioned compositions, wherein the coating further comprises a dopant anion.

In certain embodiments, the invention relates to any one of the aforementioned compositions, wherein the coating further comprises a dopant anion; and the dopant anion is selected from the group consisting of chloride, bromide, iodide, fluoride, phosphate and sulfonate.

In certain embodiments, the invention relates to any one of the aforementioned compositions, wherein the coating further comprises a dopant anion; and the dopant anion is a phosphate.

In certain embodiments, the invention relates to any one of the aforementioned compositions, wherein the coating further comprises a dopant anion; and the dopant anion is hexafluorophosphate.

In certain embodiments, the invention relates to any one of the aforementioned compositions, wherein the coating further comprises a dopant; and the dopant is nitrosonium hexafluorophosphate.

In certain embodiments, the invention relates to any one of the aforementioned compositions, wherein the coating further comprises carbonaceous particles.

In certain embodiments, the invention relates to any one of the aforementioned compositions, wherein the coating is substantially free of water.

In certain embodiments, the invention relates to any one of the aforementioned compositions, wherein the coating has an absorption maximum between about 480 nm and about 500 nm.

In certain embodiments, the invention relates to any one of the aforementioned compositions, wherein the coating has an absorption maximum at about 490 nm.

In certain embodiments, the invention relates to any one of the aforementioned compositions, wherein the onset of absorption of the coating is between about 710 nm and about 730 nm.

In certain embodiments, the invention relates to any one of the aforementioned compositions, wherein the onset of absorption of the coating is at about 720 nm.

In certain embodiments, the invention relates to any one of the aforementioned compositions, wherein the coating has a band gap that is less than the theoretically predicted band gap for polyselenophene.

In certain embodiments, the invention relates to any one of the aforementioned compositions, wherein the coating has a band gap that is less than about 1.86 eV.

In certain embodiments, the invention relates to any one of the aforementioned compositions, wherein the coating has a band gap that is about 1.80 eV, about 1.79 eV, about 1.78 eV, about 1.77 eV, about 1.76 eV, about 1.75 eV, about 1.74 eV, about 1.73 eV, about 1.72 eV, about 1.71 eV, about 1.70 eV, about 1.69 eV, or about 1.68 eV

In certain embodiments, the invention relates to any one of the aforementioned compositions, wherein the coating has a band gap that is about 1.72 eV.

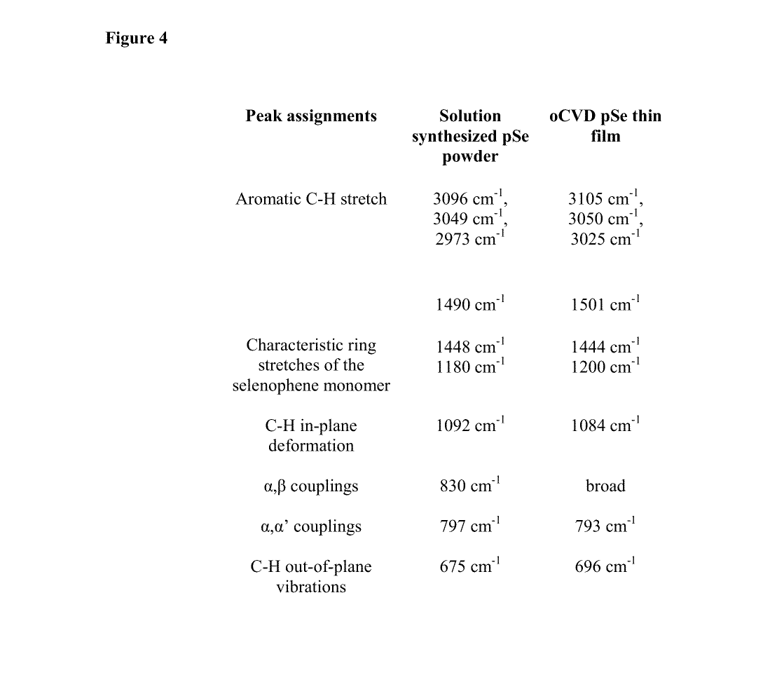

In certain embodiments, the invention relates to any one of the aforementioned compositions, wherein the coating has FT-IR absorption bands corresponding to those outlined in the right column of FIG. 4.

In certain embodiments, the invention relates to any one of the aforementioned compositions, wherein the substrate is substantially non-conductive.

In certain embodiments, the invention relates to any one of the aforementioned compositions, wherein the substrate is silicone, quartz, or paper.

In certain embodiments, the invention relates to any one of the aforementioned compositions, wherein the substrate is polystyrene, polyethyleneterephthalate, polycarbonate, polyethylenenaphthalate, polyurethane, poly(acrylonitrile-butadiene-styrene), or a copolymer thereof.

In certain embodiments, the invention relates to any one of the aforementioned compositions, wherein the substrate comprises alumina, gold, glass, silicon dioxide, quartz, alumino-silicates, tin oxide, iron oxide, chromium oxide, asbestos, talc, stainless steel, titanium dioxide, copper, nickel, zinc, lead, indium tin oxide, marble, chalk, gypsum, or barytes.

Another aspect of the invention relates to the composition obtained by the process of any one of methods discussed below.

### Methods of the Invention

One aspect of the invention relates to a method of forming a coating on a surface of a substrate, comprising the steps of:
contacting the surface of the substrate with a gaseous metal-containing oxidant, thereby forming an oxidant-enriched surface; and
contacting the oxidant-enriched surface with a gaseous monomer, thereby forming a polymer-coated surface;
wherein the gaseous monomer is optionally substituted selenophene.

One aspect of the invention relates to a method of forming any one of the aforementioned compositions, comprising the steps of:
contacting the surface of the substrate with a gaseous metal-containing oxidant, thereby forming an oxidant-enriched surface; and
contacting the oxidant-enriched surface with a gaseous monomer, thereby forming a polymer-coated surface;
wherein the gaseous monomer is optionally substituted selenophene.

In certain embodiments, the invention relates to any one of the aforementioned methods, wherein the gaseous metal-containing oxidant is selected from the group consisting of iron(III) chloride, iron(III) tosylate, potassium iodate, potassium chromate, ammonium sulfate and tetrabutylammonium persulfate.

In certain embodiments, the invention relates to any one of the aforementioned methods, wherein the gaseous metal-containing oxidant is iron(III) chloride.

In certain embodiments, the invention relates to any one of the aforementioned methods, wherein the gaseous metal-containing oxidant has an oxidation potential between about 0.5 V and about 1.0 V.

In certain embodiments, the invention relates to any one of the aforementioned methods, wherein the gaseous metal-containing oxidant has an oxidation potential of about 0.75 V.

In certain embodiments, the invention relates to any one of the aforementioned methods, further comprising the step of: subliming a metal-containing oxidant, thereby forming a gaseous metal-containing oxidant.

In certain embodiments, the invention relates to any one of the aforementioned methods, wherein the metal-containing oxidant is sublimed at a temperature of from about 200° C. to about 400° C. In certain embodiments, the invention relates to any one of the aforementioned methods, wherein the metal-containing oxidant is sublimed at a temperature of about 300° C. In certain embodiments, the invention relates to any one of the aforementioned methods, wherein the pressure prior to sublimation is from about 5 mtorr to about 100 mtorr. In certain embodiments, the invention relates to any one of the aforementioned methods, wherein the pressure prior to sublimation is about 10 mtorr, about 15 mtorr, about 20 mtorr, about 25 mtorr, about 30 mtorr, about 35 mtorr, about 40 mtorr, or about 45 mtorr. In certain embodiments, the invention relates to any one of the aforementioned methods, wherein the pressure prior to sublimation is about 15 mtorr.

In certain embodiments, the invention relates to any one of the aforementioned methods, further comprising the step of: heating the substrate.

In certain embodiments, the invention relates to any one of the aforementioned methods, wherein the substrate is heated at a temperature of from about 40° C. to about 100° C. In certain embodiments, the invention relates to any one of the aforementioned methods, wherein the substrate is heated at a temperature of about 50° C., about 60° C., about 70° C., about 80° C., or about 90° C.

In certain embodiments, the invention relates to any one of the aforementioned methods, wherein the gaseous monomer is maintained at a vapor pressure from about 50 mtorr to about 500 mtorr. In certain embodiments, the invention relates to any one of the aforementioned methods, wherein the gaseous monomer is maintained at a vapor pressure from about 50 mtorr to about 500 mtorr until a polymer coating of a desired thickness is obtained. In certain embodiments, the invention relates to any one of the aforementioned methods, wherein the gaseous monomer is maintained at a vapor pressure of about 100 mtorr, about 125 mtorr, about 150 mtorr, about 175 mtorr, about 200 mtorr, about 225 mtorr, about 250 mtorr, about 275 mtorr, or about 300 mtorr.

In certain embodiments, the invention relates to any one of the aforementioned methods, further comprising the step of: contacting the oxidant-enriched surface with a gaseous base.

In certain embodiments, the invention relates to any one of the aforementioned methods, wherein the gaseous base is an optionally substituted pyridine.

In certain embodiments, the invention relates to any one of the aforementioned methods, further comprising the step of: washing the polymer-coated surface with a solvent.

In certain embodiments, the invention relates to any one of the aforementioned methods, wherein the solvent is selected from the group consisting of water, methanol, ethanol, isopropanol, acetonitrile and mixtures thereof.

In certain embodiments, the invention relates to any one of the aforementioned methods, wherein the solvent is methanol.

In certain embodiments, the invention relates to any one of the aforementioned methods, further comprising the step of: contacting the polymer-coated surface with a dopant anion.

In certain embodiments, the invention relates to any one of the aforementioned methods, wherein the dopant anion is selected from the group consisting of chloride, bromide, iodide, fluoride, phosphate and sulfonate.

In certain embodiments, the invention relates to any one of the aforementioned methods, wherein the dopant anion is a phosphate.

In certain embodiments, the invention relates to any one of the aforementioned compositions, wherein the dopant anion is hexafluorophosphate.

In certain embodiments, the invention relates to any one of the aforementioned methods, further comprising the step of: contacting the polymer-coated surface with a dopant.

In certain embodiments, the invention relates to any one of the aforementioned methods, wherein the dopant is nitrosonium hexafluorophosphate.

In certain embodiments, the invention relates to any one of the aforementioned methods, further comprising the step of: heating the polymer-coated surface under vacuum. In certain embodiments, the invention relates to any one of the aforementioned methods, wherein the polymer-coated surface is heated to a temperature of from about 30° C. to about 100° C. In certain embodiments, the invention relates to any one of the aforementioned methods, wherein the polymer-coated surface is heated at a pressure of from about 15 mtorr to about 500 torr.

### Applications and Articles of the Invention

The unique properties of polyselenophene have led to interesting device applications, such as organic light emitting diodes (OLEDs), organic thin film transistors (OTFTs), organic photovoltaic cells (OPVs), and sensors. As described herein, the ability to deposit polyselenophene from the vapor phase will expand its utility in devices and enable the development of new organic electronics, including devices fabricated on unconventional substrates like paper and fabric.

The CVD technique disclosed herein eliminates wet processing steps that can destroy some electronic devices and organic semiconductor layers through wetting or the spin-coating process often used to apply solution-based films. CVD pSe lacks inherent acidity, which is known to corrode adjacent layers in devices, causing early failure. The CVD coating process is compatible with a variety of organic and inorganic materials since it does not depend on evenly wetting the substrate surface. Moreover, CVD can provide a uniform coating on rough, fibrous, and porous morphologies with high surface areas. Increasing the effective surface area of devices will improve operating efficiencies. In addition, the ability to conformably coat rough and sharp electrode features will reduce the chances of a short through the conducting polymer layer, resulting in longer device lifetimes.

Importantly, the formation of uniform, pure pSe films on certain substrates may lead to novel and improved organic light emitting diodes (OLEDs), photovoltaics, simple transistors, electrochromic films, and super capacitors. In addition, the methods disclosed herein may be used in energy-saving devices, such as plastic solar cells and electrochromic films for tinting architectural glass. Vapor-phase deposition of conducting organic materials for building inexpensive transistors on substrates could also be applied to polymeric radio-frequency identification (RFID) tags.

In certain embodiments, the invention relates to an article comprising a composition, wherein the composition comprises a coating on a surface of a substrate; and the coating comprises a polymer comprising selenophene repeat units. In certain embodiments, the invention relates to an article comprising any one of the aforementioned compositions.

In certain embodiments, the invention relates to any one of the aforementioned articles, wherein the article is integrated circuitry in flexible electronics.

In certain embodiments, the invention relates to any one of the aforementioned articles, wherein the article is, or is incorporated into, an organic memory device, a light-emitting diode, an electrochromic device, a display device, a photovoltaic device, a capacitor or a circuit board.

### EXEMPLIFICATION

The invention now being generally described, it will be more readily understood by reference to the following examples, which are included merely for purposes of illustration of certain aspects and embodiments of the invention, and are not intended to limit the invention.

### Example 1

### General Procedures

Materials. Selenophene (97%) and anhydrous iron chloride (97%) were purchased from Sigma-Aldrich, St. Louis, Mo.

Method. pSe films were deposited using oCVD reactor as described elsewhere. Briefly, anhydrous iron chloride was placed in a stainless steel crucible and heated under vacuum (base pressure ˜15 mTorr) to a temperature around 300° C. at which iron chloride started subliming. The samples were placed on a temperature controlled inverted stage inside the chamber. Once the iron chloride started to sublime, selenophene monomer vapor were flown into the chamber through a needle valve. The monomer vapor pressure during the reaction was maintained at 200 mTorr and the temperature of the sample stage was maintained at 70° C. This process was continued until a desired thickness of the polyselenophene was obtained. As deposited films were rinsed with methanol to remove excess iron chloride present in the pSe films prior to characterization. Silicon wafers were employed as the substrates for FT-IR and X-ray photoelectron spectroscopies, X-ray diffraction studies and scanning electron and atomic force microscopies. Quartz was used as the substrate for UV-Vis spectroscopy, trench silicon wafer was utilized to evaluate the conformal nature of the films and regular copy paper was successfully coated with pSe to show the compatibility of oCVD with paper substrates.

Characterization. The oCVD grown pSe thin films were characterized by FT-IR, UV-Vis and X-ray photoelectron spectroscopies, scanning electron and atomic force microscopies. The initially produced oCVD films were analyzed by FTIR spectroscopy using a Nexus 870, Thermo electron Corp. X-ray Photoelectron Spectroscopy (XPS) data for the polymeric films were done in a Surface Science instrument (SSI, Model: SSX-100) equipped with a monochromator. The minimization of the chi-square (and the root-mean-square parameters) was the criterion for the best fit performance in CasaXPS software. The thickness and conductivity of the films deposited on glass were measured by a KLA Tenchor P-16 surface profilometer and a four-point probe (Model: Keithley SCS-4200), respectively. Scanning electron micrographs were obtained by a tabletop Hitachi TM3000 microscope with acceleration voltage of 15 kV. Atomic force microscopy (AFM) was performed in a Veeco Nanoscope V with Dimension 3100 in tapping mode. X-ray diffraction analyses were done on a Rigaku SmartLab, using parallel beam geometry with a parallel slit analyzer using a copper radiation at 40 kV and 44 mA.

### Example 2

### Results and Discussion

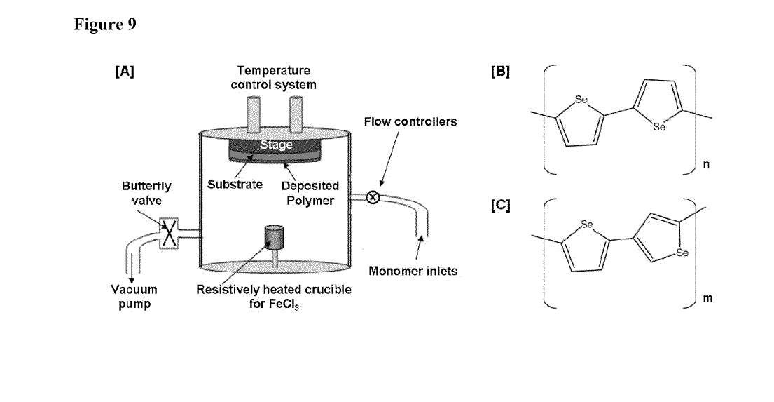

Selenophene monomer vapor was oxidatively polymerized in presence of iron chloride and the polymer was simultaneously deposited on substrates placed on an inverted stage as shown in the FIG. 9[A]. FIG. 9[B] and 9[C] show the structures of the α,α′- and α,β-coupled selenophene rings in polyselenophene. The oCVD synthesized films were dark red in color.

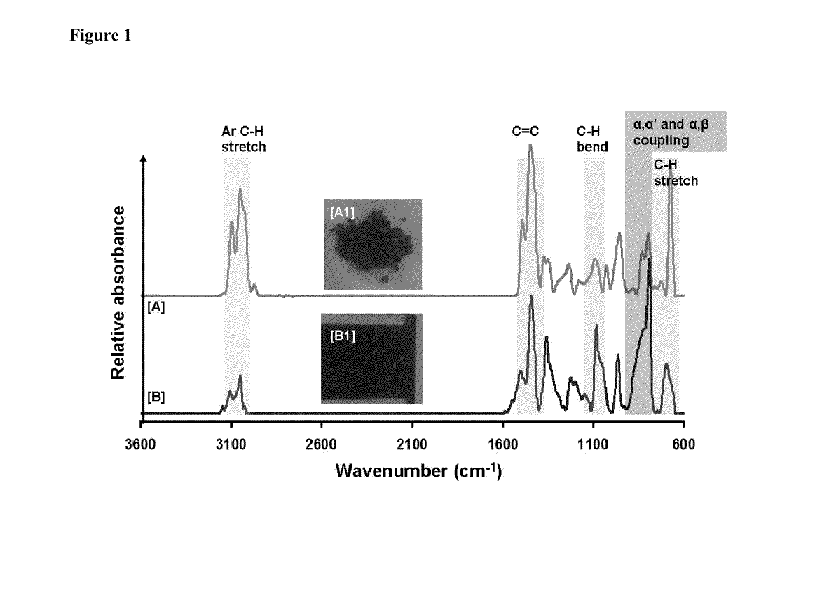

FIG. 1 shows the FT-IR spectra of pSe synthesized by solution chemistry and oCVD methods. Solution synthesized pSe was in powder form and its FT-IR spectrum was compared with the oCVD synthesized pSe films. The positions of some characteristic peaks are highlighted in the FIG. 1. For example; aromatic C—H stretching (˜3050 cm⁻¹), C—H in-plane deformation band (˜1083 cm⁻¹), C—H out-of-plane vibrations (˜690 cm⁻¹) and the peaks corresponding to the α,α′ and α,β couplings of the selenophene rings (˜790 cm⁻¹ and ˜830 cm⁻¹) and the C═C stretch of the selenophene rings (˜1500 cm⁻¹). FIG. 4 provides a comparison of the peak positions of the differently synthesized polyselenophenes in this work.

The variation in the intensities of peaks might have originated from the differences in the doping effects between the powder and film forms of the polymer or the electronic effects of the excess iron chloride present in the samples. Additionally, this difference also might have generated from the differences in the molecular weight of these polymers. The presence of peaks at ˜830 cm⁻¹ and ˜790 cm⁻¹ in both the polymers confirm that they are random, not linear polymer and selenophene monomers reacted at both α,α′ and α,β positions. However, the relative ratio of the peak of C—H out-of-plane vibrations (-690 cm⁻¹) to the peak for α,α′ and α,β couplings is much smaller in oCVD synthesized pSe films. It indicates that the molecular weight of the oCVD synthesized pSe is higher than the solution synthesized polyselenophene.

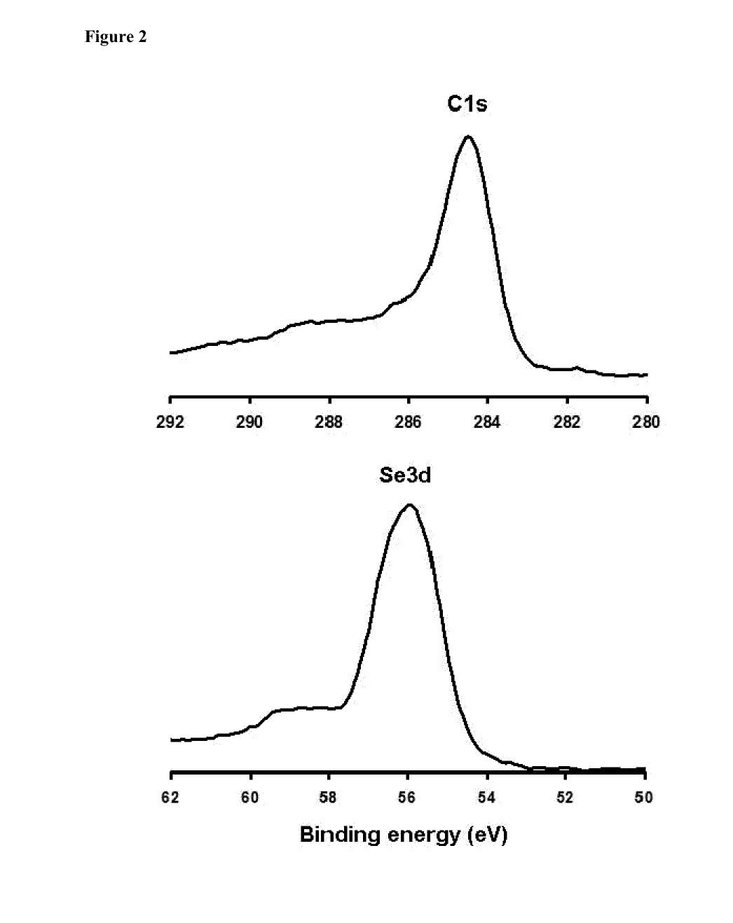

X-ray photoelectron spectroscopy experiments showed the presence of carbon, selenium, iron and chlorine in the survey scan of the oCVD deposited pSe films. Despite the presence of chlorine in the pSe films, the polymer showed no conductivity. Therefore, it is assumed that the elemental chlorine found in the XPS studies were associated with iron and came from the fraction of the iron chloride still left after the methanol rinse. Therefore, this fraction of elemental chlorine was not acting as the dopant and not sufficiently strong to make the polymer conductive. High resolution XPS scans for carbon (C1s) and selenium (Se3d) were carried out to evaluate the nature of the carbon and selenium atoms in the deposited pSe films. Both C1s and Se3d core electron spectra, as shown in FIG. 2, show oxidized states of both the elements. A shoulder at higher binding energy beyond 288 eV in C1s spectrum shows that some part of the carbon present in the polymer was oxidized. Similarly, a distinguished shoulder peak at ˜59 eV in Se3d spectrum also confirms higher binding energy oxidized Se species. The presence of these types of oxidized species is common in the conjugated polymers which are synthesized by chemical oxidation methods. Since iron chloride is a strong oxidizing agent, this possibility exists. The C:Se atomic ration was evaluated from their high resolution spectra and it was found to be 5.6:1 while their atomic ratio in the pure selenophene monomer is 4:1. This slight increase in the atomic concentration of the carbon might have originated from contamination with the environmental carbonaceous particles.

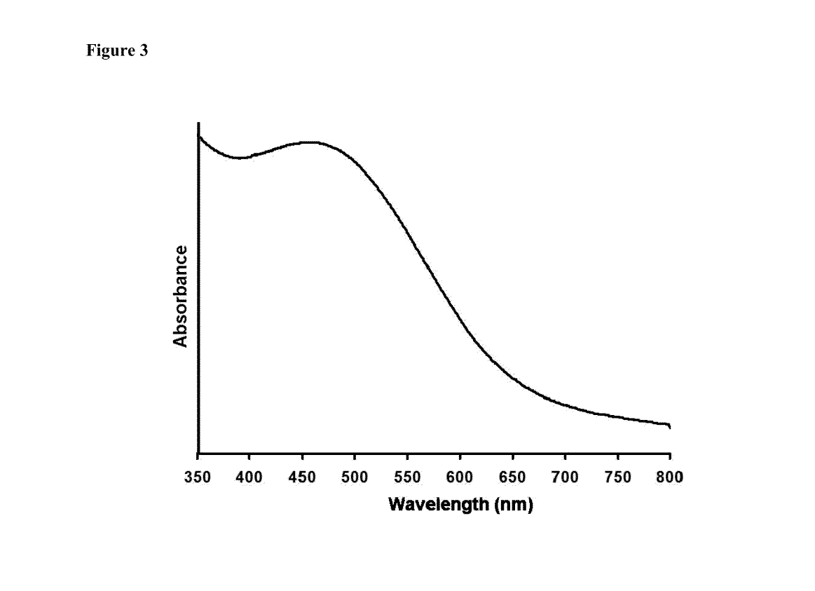

FIG. 3 shows the UV-Vis spectra of oCVD synthesized polyselenophene film on glass. The pSe film exhibits an absorption maxima around 490 nm. The onset of absorption for the oCVD grown pSe film was found to be at 720 nm as shown in FIG. 3. The band gap associated with this onset of absorption was found to be 1.72 eV which is 0.14 eV less than the theoretically predicted band gap of polyselenophenes.

Compatibility of the oCVD method and conformal nature of the oCVD synthesized pSe films was evaluated by depositing the polymer on copy paper and silicon trench wafer. pSe films were deposited on a masked copy paper and SEM images were taken (not shown). An EDS scan was also done for carbon and selenium in the same region, respectively. No significant changes in the morphology of the paper fibers in the coated and uncoated regions were observed. Furthermore, EDS scan distinctly shows the presence of selenium only in the coated region of the paper substrate.

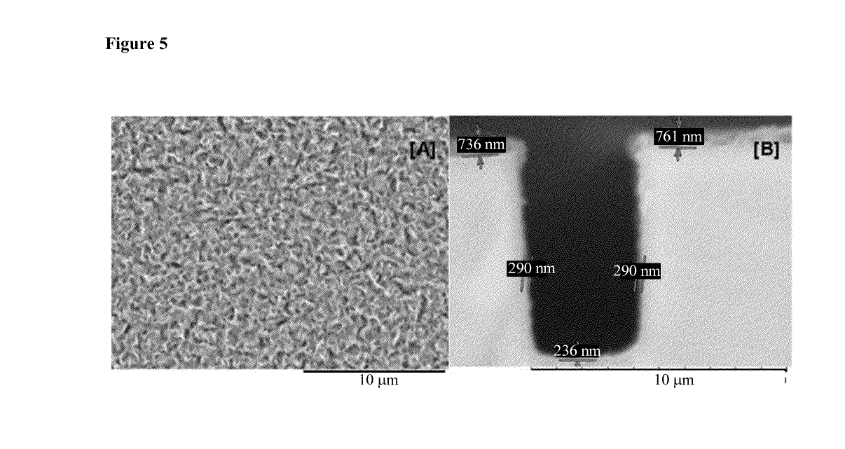

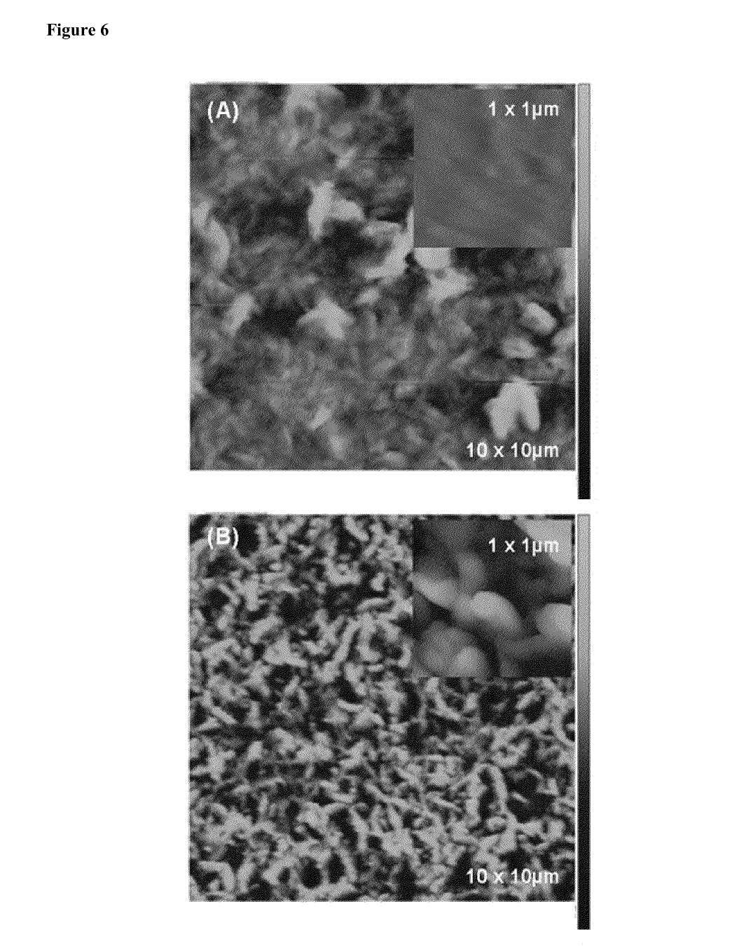

Surface morphology and conformality of thin films of the active layers are highly important for their device performances. The porous structures in the polymer film provide more surface area for improved performance of OPVs. oCVD deposited conductive polymers have been shown to have various morphological features depending on the nature of oxidants used during the respective polymer deposition. Additionally, the conformal nature of the films also changes accordingly. FIG. 5[A] shows the morphology of the top surface of the oCVD made ˜750 nm thick pSe film on silicon wafer. The submicron structural features observed in this film were absent in the films of lower thickness (>100 nm) (SEM image is not shown here). These surface characteristics were evaluated in more detail by atomic force microscopy (AFM), as shown in FIG. 6. Additionally, pSe films were deposited on trenchs of silicon wafer by oCVD method to show the conformal nature of the deposition. FIG. 5[B] shows the cross-sectional view of a silicon trench wafer that was coated with ˜750 nm thick pSe film. The thickness of the pSe films in the trench sidewall and the bottom (290 nm and 236 nm respectively) were much less than film (˜750 nm) on the top surface of the wafer. However, the films deposited inside the trench were uniform through out the side walls which could not be coated with solution synthesized insoluble polyselenophene powders.

More detailed study of the surface morphology of the oCVD deposited pSe films of various thicknesses (100 nm and 750 nm) reveal formation of nanoscale (100 nm in diameter) structures in the film as the film grows to higher thickness. The roughness of the films also increases from 11 nm to 80 nm when the film thickness changes from 100 nm to 750 nm. The inset in FIG. 6[B] shows the 100 nm diameter nanostructures found in the thicker films while, the thin film of 100 nm thickness was relatively planer as shown in inset of FIG. 6[A]. Similar surface morphologies have been previously reported for P3HTs, selenophene copolymers and also for selenophene oligomers. However this is the first time, a vapor-phase deposited active layer is found to have porous morphologies. It is important to note here that X-ray diffraction was performed to evaluate the crystallinity of both the oCVD thick and thin pSe films. Although the AFM topographical images show nanostructured morphology in thick pSe films, no peak was found in X-ray diffraction (not shown here). Therefore, all the films obtained by oCVD were amorphous. Nanostructured porous active layers are highly useful to provide higher device performances because of their higher surface area.

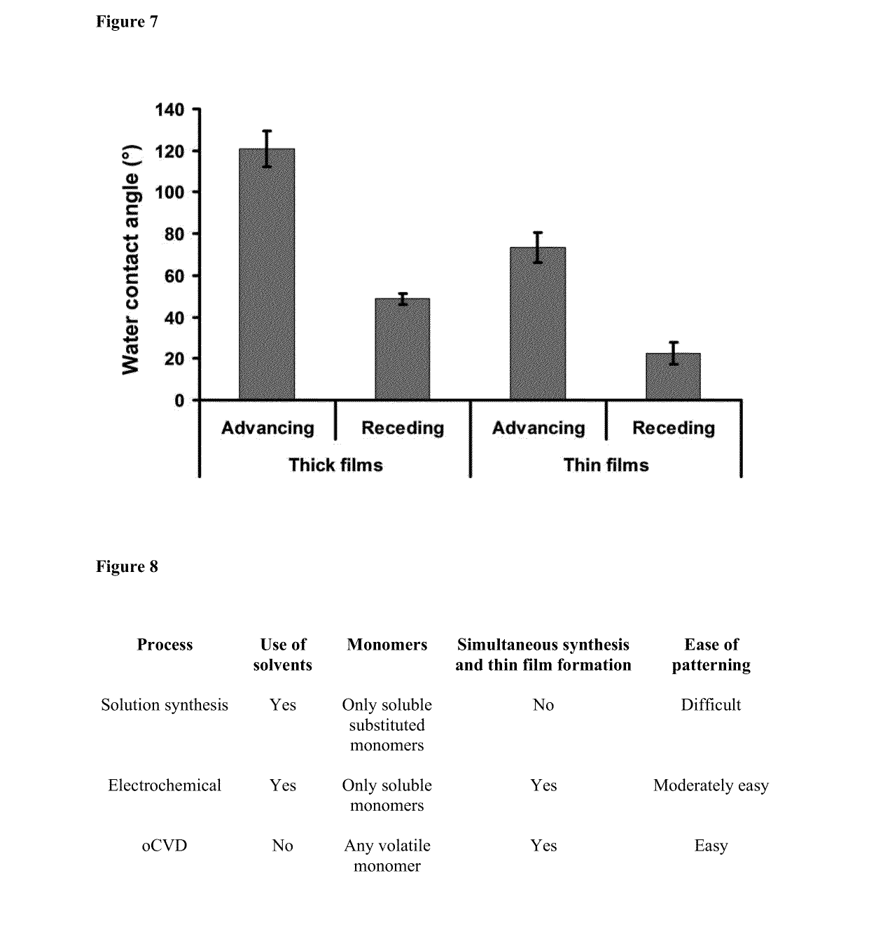

Surface morphology and surface chemistry are known to affect the surface wettability. Surface wettability of the oCVD synthesized nanostructured conducting polymers have been previously reported. In this work, the surface chemistry is identical for oCVD synthesized pSe films of two different thicknesses. However, a significant difference in the water contact angle was found, as shown in FIG. 7, only due to the variation in the surface roughness. The advancing angles of thick and thin pSe films were 120.8±8.5° and 73.2±7.2° while the receding angles were 48.7±2.6° and 22.5±5.3°, respectively. Since thicker pSe films were significantly rougher than the thinner films, as observed in AFM studies, both the advancing and receding contact angles were higher for the thicker films. The difference between the advancing and receding angles (advancing angle−receding angle) for the thicker films (˜70°) was also higher than that of the thinner films (˜50°).

### INCORPORATION BY REFERENCE

All of the U.S. patents and U.S. patent application publications cited herein are hereby incorporated by reference.

### EQUIVALENTS

Those skilled in the art will recognize, or be able to ascertain using no more than routine experimentation, many equivalents to the specific embodiments of the invention described herein. Such equivalents are intended to be encompassed by the following claims.

We claim:

1. A method of forming a coating on a surface of a substrate, comprising the steps of:
subliming a metal-containing oxidant in a reactor at a temperature, thereby forming a gaseous metal-containing oxidant;
contacting the surface of the substrate with the gaseous metal-containing oxidant, thereby forming an oxidant-enriched surface; and
contacting the oxidant-enriched surface with a gaseous monomer, thereby forming a polymer-coated surface;
wherein the gaseous monomer is optionally substituted selenophene.

2. The method of claim 1, wherein the gaseous metal-containing oxidant is selected from the group consisting of iron(III) chloride, iron(III) tosylate, potassium iodate, potassium chromate, ammonium sulfate and tetrabutylammonium persulfate.

3. The method of claim 1, further comprising the step of: heating the substrate at a temperature of from about 40° C. to about 100° C.

4. The method of claim 1, wherein the gaseous monomer is unsubstituted selenophene.

5. The method of claim 1, wherein the polymer coating comprises α,α′- or α,β-coupled selenophene repeat units.

6. The method of claim 1, wherein the thickness of the polymer coating is from about 50 nm to about 1500 nm.

7. The method of claim 1, wherein the polymer coating is conductive.

8. The method of claim 1, wherein the polymer coating has a conductivity of between about 0 S/cm and about 150 S/cm.

9. The method of claim 1, wherein the polymer coating has a band gap that is less than about 1.86 eV.

10. The method of claim 1, wherein the polymer coating has a band gap that is about 1.72 eV.

11. The method of claim 1, wherein the substrate is substantially non-conductive.

12. The method of claim 1, wherein the substrate is silicone, quartz, or paper.

13. A composition, comprising a coating on a surface of a substrate, wherein the coating comprises a polymer comprising selenophene repeat units.

14. The composition of claim 13, wherein the coating has a band gap that is less than about 1.86 eV.

15. The composition of claim 13, wherein the coating has a band gap that is about 1.72 eV.

16. The composition of claim 13, wherein the substrate is substantially non-conductive.

17. The composition of claim 13, wherein the substrate is silicone, quartz, or paper.
